(19) United States
(12) Patent Application Publication
(10) Pub. No.: US 2026/0136733 A1
(43) Pub. Date: May 14, 2026

(54) DISPLAY APPARATUS

(71) Applicant: LG Display Co., Ltd., Seoul (KR)

(72) Inventors: Chan KIM, Paju-si (KR); Jae-Hoon JANG, Paju-si (KR); Joon-Kwon MOON, Paju-si (KR); Jae-Kyung SHIN, Paju-si (KR)

(73) Assignee: LG Display Co., Ltd., Seoul (KR)

(21) Appl. No.: 19/183,544

(22) Filed: Apr. 18, 2025

(30) Foreign Application Priority Data
Nov. 13, 2024 (KR) 10-2024-0161042

(51) Int. Cl. H10H 29/03; H10H 29/49

(52) U.S. Cl. CPC H10H 29/03; H10H 29/49

(57) ABSTRACT

In one or more examples, a display apparatus includes a magnetic pad on an adhesive layer disposed on a display panel and a light-emitting diode package arranged on the magnetic pad. The light-emitting diode can be transferred to the display panel with precision by magnetism.

### CROSS-REFERENCE TO RELATED APPLICATIONS

This application claims the benefit of and priority to Korea Patent Application No. 10-2024-0161042, filed in the Republic of Korea on Nov. 13, 2024, the entire contents of which are expressly incorporated herein by reference for all purposes.

### BACKGROUND

### 1. Technical Field

The present disclosure relates to a display apparatus, and more particularly to, for example, without limitation, a display apparatus with a precise location of a light-emitting element.

### 2. Description of the Related Art

A display apparatus has been applied to various electron devices such as TV, a mobile device, a note book and a tablet PC. The display apparatus comprises a light-emitting display apparatuses such as an organic light-emitting diode (OLED) displays that emit light on their own, and a liquid crystal displays (LCDs) that require a separate light source.

Currently, a display apparatus including a light-emitting diode (LED) has been attracted as a next generation display apparatus. The LED comprises inorganic materials instead of organic materials so that the display apparatus including the LED has advantages of rapid lightning speed, beneficial luminous efficiency and high brightness compared to the OLED display.

The description of the related art should not be assumed to be prior art merely because it is mentioned in or associated with this section. The description of the related art includes information that describes one or more aspects of the subject technology, and the description in this section does not limit the invention.

### SUMMARY

Accordingly, some embodiments of the present disclosure are directed to a display apparatus and a process of fabricating a display apparatus that substantially obviates one or more of the problems due to the limitations and disadvantages of the related art.

An aspect of the present disclosure is to provide a display apparatus with beneficial precision when a light-emitting diode is transferred to a display panel.

Additional features and aspects will be set forth in the description that follows, and in part will be apparent from the description, or can be learned by practice of the disclosed concepts provided herein. Other features and aspects of the disclosed concept can be realized and attained by the structure particularly pointed out in the written description, or derivable therefrom, and the claims hereof as well as the appended drawings.

One or more aspects of the present disclosure relate to a display apparatus that comprises a display panel and a light-emitting diode (LED) package each of which includes a magnetic pad inducing an electromagnetic force. The electromagnetic force enables the micro LED package to be transferred efficiently to the display panel and the display device with a large area.

To achieve these and other aspects of the inventive concepts, as embodied and broadly described, in one aspect, the present disclosure provides a display apparatus that comprises a display apparatus that comprises a display panel; a plurality of adhesive layers disposed on the display panel; a first magnetic pad disposed on at least one of the plurality of adhesive layers; and a light-emitting diode (LED) package disposed on the first magnetic pad.

In one embodiment, the LED package can comprise a support; a plurality of micro LEDs arranged on the support; and a second magnetic pad positioned under the support.

In another embodiment, the LED package can further comprise an electrode spaced apart from the second magnetic pad under the support.

The display apparatus can further comprise a plurality of bonding layers arranged on an adhesive layer on which the first magnetic pad is not arranged, wherein the adhesive layer is a layer among the plurality of adhesive layers.

The electrode of the LED package can be disposed corresponding to each of the bonding layers.

The first magnetic pad and the second magnetic pad can have magnetic fields of different polarities.

The second magnetic pad can be positioned correspondingly on the first magnetic pad.

The second magnetic pad can be arranged in multiples per the LED package.

In one embodiment, the display panel can further comprise a protrusion disposed to surround the LED package.

As an example, the protrusion can comprise a first protrusion protruding upwardly from an upper surface of the display panel; and a second protrusion having a shape inclined from an upper surface of the first protrusion.

An upper surface of the support can be placed at a substantially same position as an upper surface of the second protrusion.

In another embodiment, the display apparatus can further comprise a first fixing layer disposed on the display panel and disposed to surround outer sides of an adhesive layer, the first magnetic pad, the second magnetic pad and the support, wherein the adhesive layer is a layer among the plurality of adhesive layers.

As an example, an upper surface of the first fixing layer can be placed at a substantially same as an upper surface of the second protrusion.

In another embodiment, the display panel can further comprise a nano coating layer disposed on the second protrusion.

In another embodiment, the display apparatus can further comprise a second fixing layer placed on the display panel and arranged to surround a portion of an outside of the support; and a third fixing layer disposed on the second fixing layer.

In still another embodiment, the display apparatus can further comprise a fourth fixing layer disposed on the display panel and arranged to surround the plurality of adhesive layers, the first magnetic pad and the second magnetic pad.

The first magnetic pad and the second magnetic pad can have magnetic fields of different polarities and the second magnetic pad can be positioned correspondingly on the first magnetic pad.

The first magnetic pad can be arranged in multiples per the LED package.

In another aspect, the present disclosure provides a process of fabricating a display apparatus, the process comprises arranging a plurality of adhesive layers on a display panel; arranging a first magnetic pad on the plurality of the adhesive layers; and arranging a light-emitting diode (LED) package on the first magnetic pad, wherein the LED package comprises a second magnetic pad having a magnetic field, wherein a polarity of the magnetic field of the second magnetic pad is opposite to a polarity of a magnetic field of the first magnetic pad, and wherein the second magnetic pad is placed on the first magnetic pad by magnetism.

In one embodiment, the display panel can be vibrated to align a central axis of the LED package with a central axis of the display panel when the second magnetic pad is placed on the first magnetic pad by magnetism.

In one or more embodiments, the display apparatus enables the transfer of micro LEDs of 1.0 um or less in size with a precision of 1 um or less through a transfer process using magnetism. The LED package can be accurately placed in the desired location through the vibration of the display panel and the protrusion arranged on the display panel.

In addition, the transfer efficiency of the micro LED package can be maximized by preventing the transferred LED package from being detached or separated from the display panel through the fixing layer.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1 illustrates a plane view of a display apparatus in accordance with an embodiment of the present disclosure.

FIG. 2 illustrates a functional block diagram of a display apparatus in accordance with an embodiment of the present disclosure.

FIG. 3 illustrates a schematic circuit diagram of a pixel circuit included in the display apparatus in accordance with an embodiment of the present disclosure.

FIG. 4 illustrates a schematic cross-sectional view of a display apparatus before a micro LED package is transferred to a display panel in accordance with one embodiment of the present disclosure.

FIG. 5 illustrates a schematic cross-sectional view of a micro light-emitting diode in accordance with an embodiment of the present disclosure.

FIG. 6 illustrates a schematic cross-sectional view of a display apparatus before a micro LED package is transferred to a display panel in accordance with one embodiment of the present disclosure.

FIG. 7 illustrates a schematic cross-sectional view of a display apparatus after a micro LED package is transferred to a display panel in accordance with one embodiment of the present disclosure.

FIG. 8 illustrates a schematic cross-sectional view of a display apparatus before a micro LED package is transferred to a display panel in accordance with another embodiment of the present disclosure.

FIG. 9 illustrates an enlarged cross-sectional view of an area I in FIG. 7 in accordance with another embodiment of the present disclosure.

FIG. 10 illustrates an enlarged cross-sectional view of an area I in FIG. 7 in accordance with another embodiment of the present disclosure.

FIG. 11 illustrates an enlarged cross-sectional view of an area I in FIG. 7 in accordance with another embodiment of the present disclosure.

FIG. 12 illustrates an enlarged cross-sectional view of an area I in FIG. 7 in accordance with another embodiment of the present disclosure.

FIG. 13 illustrates a schematic cross-sectional view of a micro light-emitting diode in accordance with another embodiment of the present disclosure.

FIGS. 14 and 15 illustrate schematic cross-sectional views of a display apparatus before and after a micro LED package is transferred to a display panel, respectively, in accordance with another embodiment of the present disclosure.

FIG. 16 illustrates various arrangements of a magnetic pad in another embodiment of the present disclosure.

FIGS. 17 to 20 illustrate devices including the display apparatus in accordance with embodiments of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing embodiments of the present disclosure are merely illustrative examples, and thus the present disclosure is not limited to the illustrated examples. The same reference numerals refer to the same components throughout this disclosure unless otherwise specified. Further, in the following description of the present disclosure, where a detailed description of a known related art may unnecessarily obscure the gist of the present disclosure, the detailed description thereof may be omitted herein or may be briefly discussed.

Where terms such as “including,” “having,” “comprising,” and the like are used in this disclosure, other parts can be added unless a more limiting term like “only” is used herein. Further, where a component is expressed as being singular, being plural is included, and vice versa, unless otherwise specified. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

A phrase “substantially same” or “nearly same” may indicate, for example, a degree of being considered as being equivalent to each other taking into account minute differences due to errors in the manufacturing process.

In analyzing or construing a component, an error range should be interpreted as being included even where there is no explicit description.

In describing a positional relationship, for example, where a positional relationship of two parts/layers is described as being “over,” “on,” “above,” “below,” “under,” “next to,” or the like, one or more other parts/layers can be provided between the two parts/layers, unless a more limiting term like “immediately” or “directly” is used therewith.

When a component or layer is referred to as being “on” another component or layer, it includes both instances where the other component is directly on the other component or layer, or where there is another layer or component intervening therebetween.

In describing a temporal relationship, for example, where a temporal predecessor relationship is described as being “after,” “subsequent,” “next to,” “prior to,” or the like, unless a more limiting term like “immediately” or “directly” is used, cases that are not continuous or sequential can also be included.

Although the terms first, second, and the like may be used to describe various components, these components are not substantially limited by these terms. These terms are used only to refer to one component separately from another component, and may not define any particular order or sequence. Therefore, a first component described below can substantially be a second component, and vice versa, within the technical spirit of the present disclosure.

In describing components of this specification, terms such as first, second, A, B, (a), or (b) may be used. These terms are only intended to distinguish the components from other components, and the nature, order, sequence, or numbers of components are not limited by the terms.

When a component is described as being “connected,” “coupled,” “connected,” or “attached,” to another component, it should be understood that the component may be directly connected, coupled, connected, or attached to the other component, but that other components may be interposed between each component that may be indirectly connected, coupled, connected, or attached without specifically expressly stating so.

When a component or layer is described as being “contacted,” or “overlapping,” it should be understood that the component or layer may directly contact or overlap the other component or layer, but that other components may be interposed between each component that may be indirectly contacted or overlapped without specifically expressly stating so. “At least one” should be understood to include any combination of one or more of the associated components. For example, “at least one of the first, second, and third components” can be understood to include not only the first, second, or third components, but also any combination of two or more of the first, second, and third components.

“First direction,” “Second direction,” “Third direction,” “X-axis direction,” “Y-axis direction,” and “Z-axis direction” should not be interpreted as merely geometric relationships in which the relationships between each other are perpendicular, but can mean a wider directionality within the scope in which the configuration of this specification can function functionally.

Features of various embodiments of the present disclosure can be partially or entirely united or combined with each other, technically various interlocking and driving are possible, and each of the embodiments can be independently implemented with respect to each other or implemented together in a co-dependent relationship.

All the components of each display device according to all embodiments of the present disclosure are operatively coupled and configured.

Reference will now be made in detail to aspects of the disclosure, examples of which are illustrated in the accompanying drawings. Wherever possible, the same reference numbers will be used throughout the drawings to refer to the same or like parts.

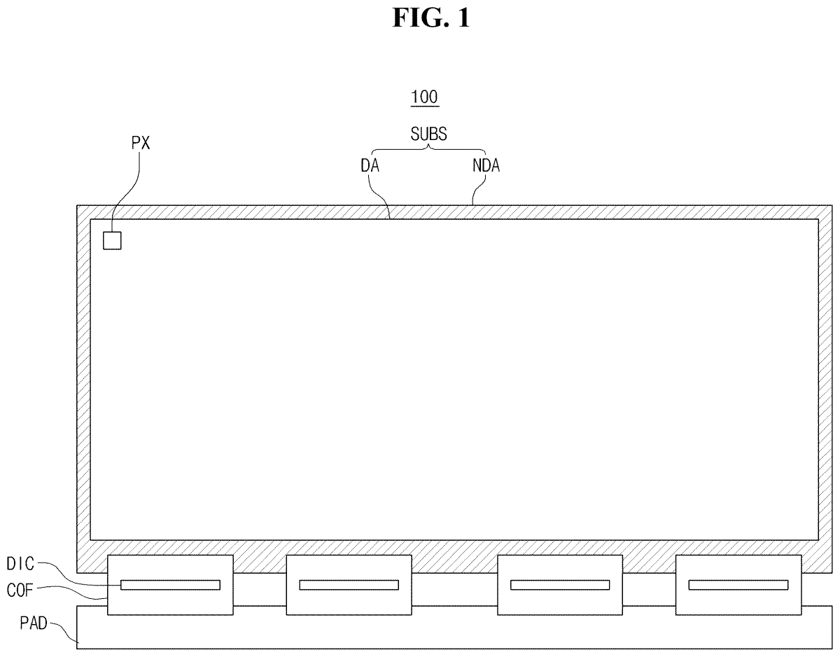

FIG. 1 illustrates a plane view of a display apparatus in accordance with an embodiment of the present disclosure.

As illustrated in FIG. 1, a display apparatus 100 comprises a substrate SUBS including a display area DA and a non-display area NDA. The substrate SUBS can comprise glass and/or plastic. When the substrate SUB is made of plastic, the substrate SUBS can be a flexible substrate. The flexible substrate can be made of a flexible resin and can comprise the same or different materials.

The display area DA can be configured to position on the substrate SUBS and the non-display area NDA can be positioned outside of the display area DA. The non-display area NDA can comprise a pad portion PAD at one side thereof. For example, the pad portion PAD can be positioned, but is not limited to, at lower side of the non-display area NDA. The COF film COF can be provided on the pad portion PAD. The COF film COF can include a driver integrated circuit DIC.

The display area DA can comprise a plurality of pixels PX. In one embodiment, the pixel PX can emit red color light, green color light and a blue color light. Alternatively, the pixel PX can emit red color light, green color light, blue color light and white color light. The display area DA can comprise a GIP driver for applying a gate driving signal to the display area DA at one side thereof. A Chip on Film (COF) can be attached to the pad portion PAD provided on one side of the display area DA. For example, the GIP driver can be supplied to a right side of the display area DA and the pad portion Pad can be supplied to a lower side of the display area DA. A data signal and a power can be applied to plural signal lines provided in the display area DA through the COF.

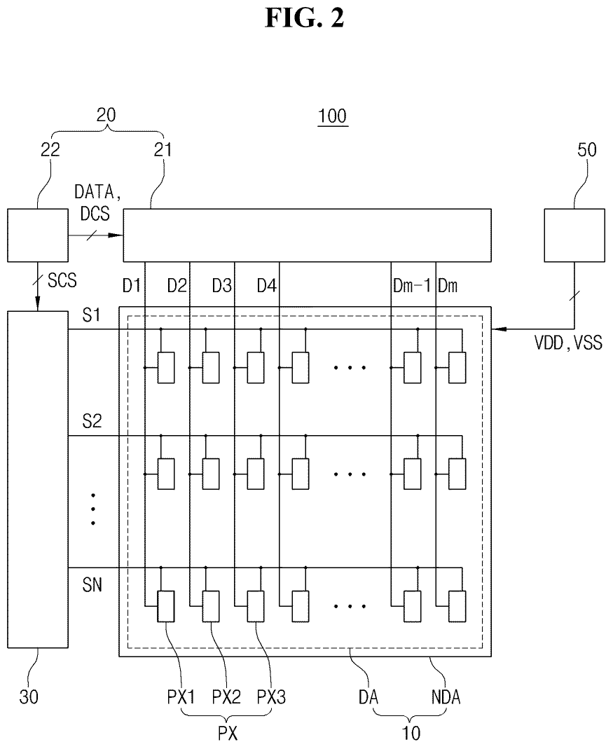

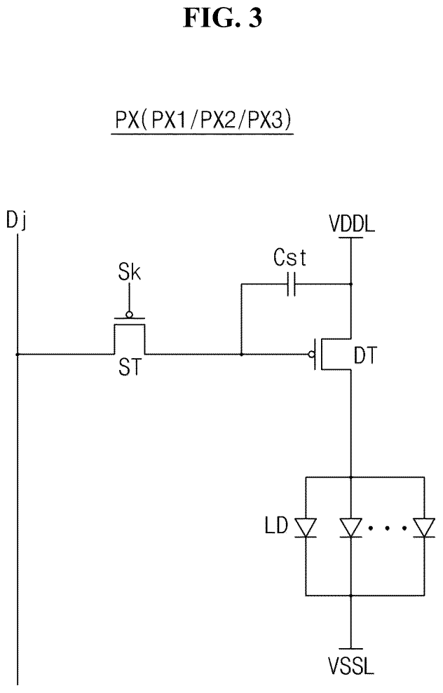

FIG. 2 illustrates a functional block diagram of a display apparatus in accordance with an embodiment of the present disclosure. FIG. 3 illustrates a schematic circuit diagram of a pixel circuit included in the display apparatus in accordance with an embodiment of the present disclosure.

As illustrated in FIGS. 2 and 3, the display apparatus 100 in accordance with an embodiment can comprise a display panel 10, a driving circuit 20, a scan driver 30 and a power supply circuit 50.

The driving circuit 20 can comprise a data driver 21 and a timing controller 22.

As described above, the display area DA in the display panel 10 can be an area where pixels PX are formed to display an image. The display panel 10 can comprise data lines D1 to Dm (wherein m is an integer equal to or greater than 2), scan lines S1 to Sn (wherein n is an integer equal to or greater than 2) crossing the data lines D1 to Dm, a high-potential line to which a high-potential voltage is supplied, a low-potential line to which a low-potential voltage is supplied, and pixels PX connected to the data lines D1 to Dm and the scan lines S1 to Sn.

In one embodiment, each of the pixels PXs can comprise a first sub-pixel PX1, a second sub-pixel PX2 and a third sub-pixel PX3. The first sub-pixel PX1 can emit a first color light with a first wavelength, the second sub-pixel PX2 can emit a second color light with a second wavelength and the third sub-pixel PX3 can emit a third color light with a third wavelength. As an example, the first color light can be a red color light, the second color light can be a green color and the third color light can be a blue color light, but is not limited thereto. In FIG. 2, each pixel PX comprises three sub-pixels, but is not limited thereto. In other words, each of the pixels PXs can comprise four or more sub-pixels.

Each of the first sub-pixel PX1, the second sub-pixel PX2 and the third sub-pixel PX3 can be connected to one of the data lines D1 to Dm, one of the scan lines S1 to Sn and the high-potential voltage line. As illustrated in FIG. 3, each of the first sub-pixel PX1, the second sub-pixel PX2 and the third sub-pixel PX3 can comprise a plurality of light-emitting diodes LDs, a plurality of transistors for supplying current to the light-emitting diodes LDs and at least one capacitor Cst. Alternatively, each of the first sub-pixel PX1, the second sub-pixel PX2 and the third sub-pixel PX3 can comprise one light-emitting diode LD and at least one capacitor Cst.

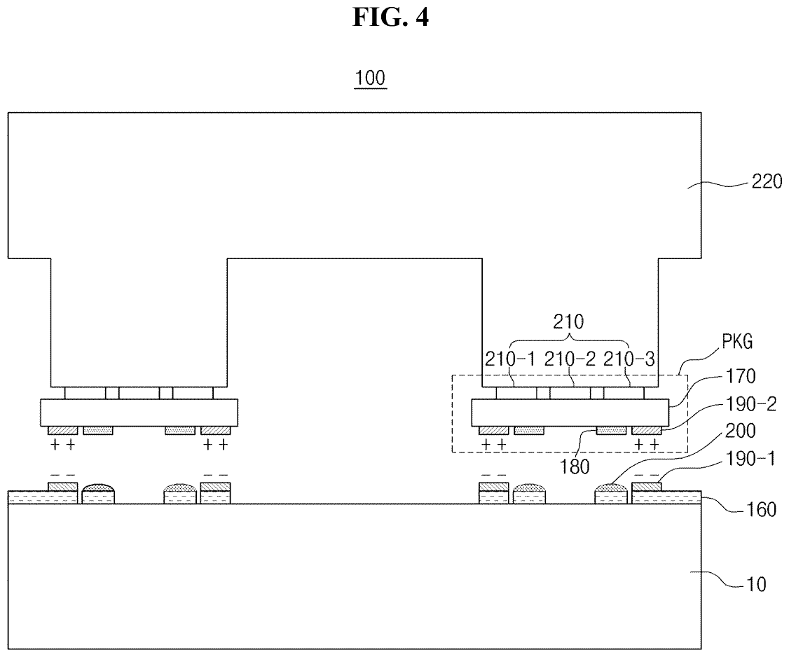

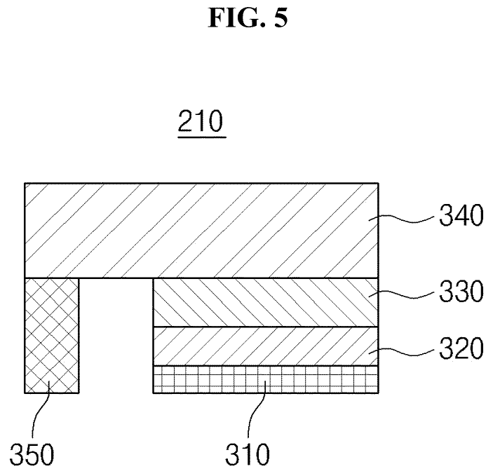

Each of the light-emitting diodes LDs can be a semiconductor light-emitting diode including a first electrode 310 (FIG. 5), a plurality of conductive semiconductor layers 320, 330 and 350 (FIG. 5) and a second electrode 340 (FIG. 4). As an example, the first electrode can be an anode electrode or a p-type electrode and the second electrode can be a cathode electrode or an n-type electrode, but is not limited thereto.

With referring to FIG. 3, the plurality of transistors can comprise a driving transistor DT supplying current to the light-emitting diodes LD, and a scan transistor ST supplying data voltage to a gate electrode of the driving transistor DT. The driving transistor DT can comprise the gate electrode connected to a source electrode of the scan transistor ST, a source electrode connected to the high-potential voltage line applying the high-potential voltage, and a drain electrode connected to the first electrode of the light-emitting diode LD. The scan transistor ST can comprise a gate electrode connected to the scan line Sk (k is an integer satisfying 1≤k≤n), a source electrode connected to the gate electrode of the driving transistor DT, and a drain electrode connected to the data line Dj (j is an integer satisfying 1≤j≤m).

The capacitor Cst can be arranged between the gate electrode and the source electrode of the driving transistor DT. The storage capacitor Cst can charge voltages corresponding to the difference between the gate voltage and the source voltage of the driving transistor DT. Each of the driving transistor DT and the scan transistor ST can be formed as a thin film transistor.

In FIG. 3, each of the first sub-pixel PX1, the second sub-pixel PX2 and the third sub-pixel PX3 comprises one driving transistor DT, one scan transistor ST and one capacitor Cst to form a 2 TIC (2 transistors and 1 capacitor), but is not limited thereto. Alternatively, each of the first sub-pixel PX1, the second sub-pixel PX2 and the third sub-pixel PX3 can comprise a plurality of the scan transistors STs and a plurality of the capacitors Cst.

With referring to FIG. 2, the driving circuit 20 output signals and voltages for driving the display panel 10. The driving circuit 20 can comprise the data driver 21 and the timing controller 22.

The data driver 21 receives digital video data DATA and source control signal CDS from the timing controller 22. The data driver 21 convert the digital video data DATA to analog data voltages by the source control signal DCS and supplies the analog data voltages to the data lines D1 to Dm of the display panel 10.

The timing controller 22 receives the digital video data DATA and timing signals form a host system. The timing signals can comprise vertical sync signal, horizontal sync signal, data enable signal and a dot clock. The host system can comprise, but is not limited to, an application processor of a mobile phone or a tablet PC, a monitor, TV system on chip.

The scan driver 30 receives a scan control signal SCS from the timing controller 22. The scan driver 30 generates a scan signal by the scan control signal SCS and supplies the scan signal to the scan lines S1 to Sn of the display panel 10. The scan driver 30 can comprise a plurality of transistors and can be arranged in the non-display area NDA of the display panel 10. Alternatively, the scan driver 30 can be formed as an integrated circuit. In this case, the scan driver 30 can be mounted on a gage flexible film attached on other side of the display panel 10.

The power supply circuit 50 can generate the high-potential voltage VDD and the low-potential voltage VSS form a main power supply for driving the light-emitting diodes LDs of the display panel 10 and supply the voltages to the high-potential voltage line and the low-potential voltage line of the display panel 10, respectively. In addition, the power supply circuit 50 can generate driving voltages for the driving circuit 20 and the scan driver 30 from the main power.

In the present disclosure, the display apparatus 100 can use a micro light-emitting diode (micro LED) as the light-emitting diode LD. The components of the display apparatus will be described in more detail with referring to FIGS. 4-6.

As illustrated in FIGS. 4-6, a plurality of components and/or areas for transferring a light-emitting diode package (LED package) PKG onto the display panel 10 can be arranged. A plurality of adhesive layers 160 can be arranged to the display panel 10. Each of the adhesive layers 160 can have a predetermined height and can have a different width depending on the locations.

A first magnetic pad 190-1 can be placed on at least one of the adhesive layers 160. Alternatively, a bonding layer 200 can be placed on the adhesive layer 160 onto which the first magnetic pad 190-1 is not placed with spaced apart from the first magnetic pad 190-1. As an example, the boding layer 200 can be a soldering layer including metal material.

The LED package PKG transferred to the display panel 10 can comprise a support 170, a plurality of micro LEDs 210, a second magnetic pad 190-2 and an electrode 180.

The plural micro LEDs 210 can be arranged on the support 170, and can comprise a first micro LED 210-1, a second micro LED 210-2 and a third micro LED 210-3. For example, one of the first micro LED 210-1, the second micro LED 210-2 and the third micro LED 210-3 can be a red light-emitting diode, another of the first micro LED 210-1, the second micro Led 210-2 and the third micro LED 210-3 can be green light-emitting diode, and the rest of the first micro Led 210-1, the second micro LED 210-2 and the third micro LED 21-3 can be a blue light-emitting diode, but is not limited thereto. It is possible to various colors including white light by combining red light, green light and blue light emitted from the plural micro LEDs 210. In one embodiment, each of the micro LEDs 210 can be mainly made of gallium nitride (GaN) together adding indium (In) and/or aluminum (Al) so that the micro LEDs 210 can be implemented as a high-output light-emitting diode that emits various types of light including blue color light.

In one embodiment, the LED package PKG in which the plural micro LEDs 210 are arranged on the support 170 are transferred to the display panel 10. Compared to the process of transferring micro LED individually, the number of transfer can be reduced in the transfer process that is performed as a LED package PKG including the plural micro LEDs 210. Accordingly, it is possible to fabricate high-resolution displays. Therefore, transferring micro LEDs 210 as the LED package PKG increases process efficiency, but also enables development high-resolution display models by transferring micro LEDs 210 of a smaller size.

Each of the plural micro LEDs 210 can be a light-emitting diode of a flip chip type in one embodiment. With referring to FIG. 5, each of the micro LEDs 210 can comprise a p-type electrode 310 of a lower electrode, a p-type semiconductor layer 320 disposed on the p-type electrode 310, an active layer 330 disposed on the p-type semiconductor layer 320, an n-type semiconductor layer 340 disposed on the active layer and an n-type electrode 350 of an upper electrode horizontally spaced apart from the p-type electrode 310 on the n-type semiconductor layer 340. In this case, both the p-type electrode 310 and the n-type electrode 350 can be electrically connected to a p-electrode and an n-electrode, respectively, of a wiring board at the bottom of the semiconductor light-emitting diode 210 as an example of the light-emitting diode of the flip chip type.

In one embodiment, the electrode 180 that is electrically connected to the p-type and n-type electrodes 310 and 350 of the plural micro LEDs 210, of the LED package 180 can be disposed under the support 170. In one embodiment, a plurality of the electrodes 180 in each LED package PKG can be arranged under the support 170, and a plurality of the second magnetic pads 190-2 can be arranged with spaced apart from the electrodes 180.

The first magnetic pad 190-1 arranged on the display panel 10 and the second magnetic pad 190-2 arranged under the support 170 can have magnetic fields of different directions or different polarities, and the second magnetic pad 190-2 can be placed correspondingly on the first magnetic pad 190-1, it is possible to solve problems such as detachment or separation of the micro LEDs 210 that occur frequently during the transfer process. In this case, the second magnetic pad 190-2 can be placed on the first magnetic pad 190-1, and the second magnetic pad 190-2 placed or settled at a set position of the first magnetic pad 190-1 to correct the alignment of the LED package PKG, thereby, reducing the occurrence of micro errors.

As an example of the present disclosure, the type of the micro LEDs 210 of the flip chip type has been described. Alternatively, the micro LEDs 210 of a horizontal type chip can be also applied, but the present disclosure is not limited thereto.

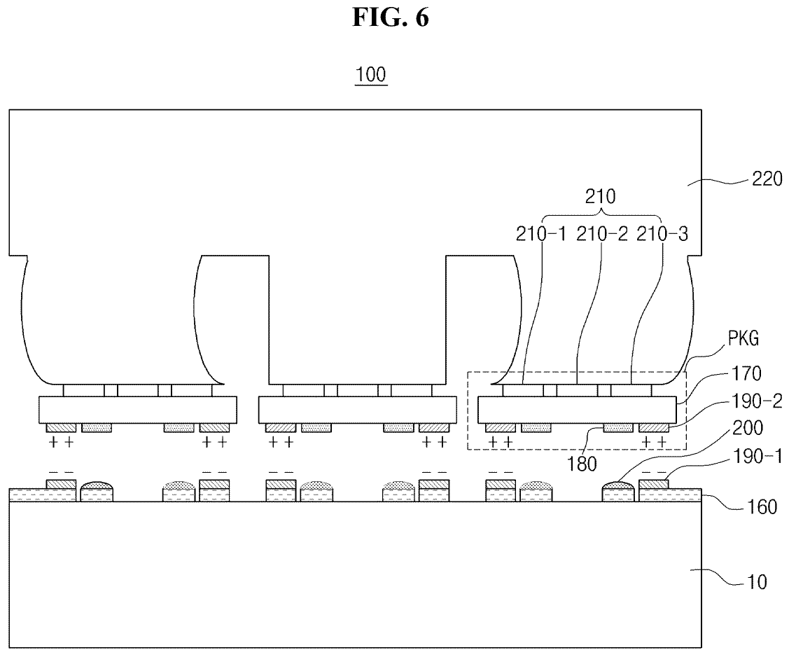

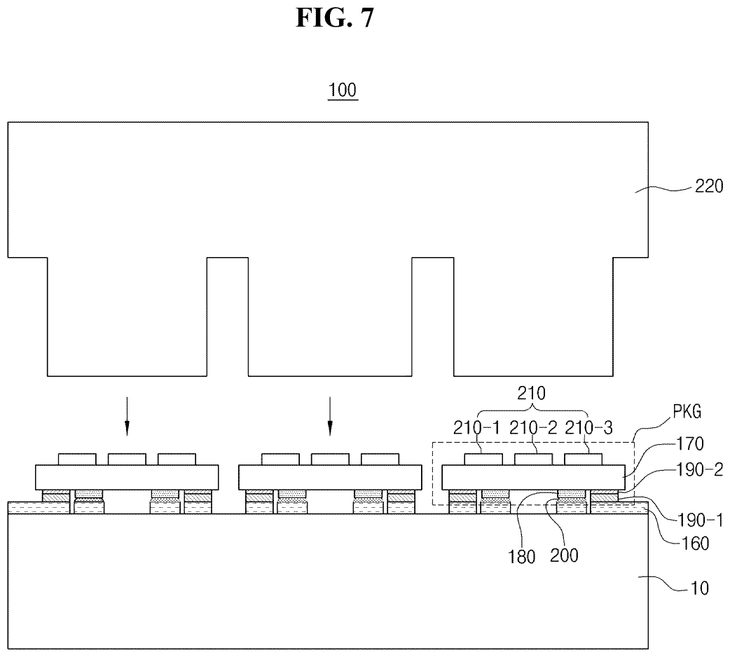

More particularly, with referring to FIGS. 6 and 7, a stamp 220 that transfers and arranging the LED package PKG to the display panel 10 in the display apparatus 100 can comprise a material with low hardness. For example, the stamp 200 can comprise, but is not limited to, a silicone-containing elastomeric polymer such as polydimethylsiloxane (PDMS). The material can be suitable for transferring fine structures because it is flexible, transparent and has high elasticity. In addition, polydimethylsiloxane (PDMS) can precisely reproduce a desired pattern depending on the process, so it can help efficiently transfer the micro LEDs 210, but the material of the stamp 220 is not limited thereto.

As described above, the stamp 220 can be transferred to place the LED package PKG onto the display panel 10. In one embodiment, a portion of the stamp 220 can be bent by magnetic force between the first magnetic pad 190-1 and the second magnetic pad 190-2 in the course of placing the LED package PKG onto the display panel 10. The elastic stamp 220 can be partially bent by the magnetic force to help the LED package PKG to be in the designed position. This can improve the precision with which the LED package PKG is transferred and maximize process efficiency.

As illustrated in FIG. 7, the second magnetic pad 190-2 of the LED package PKG can be placed on the first magnetic pad 190-1 arranged on at least one of the adhesive layers 160, and the electrode 180 of the LED package PKG can be placed on the bonding layer 200 arranged on other adhesive layer 160 in the display apparatus 100 where the LED package PKG is transferred to the display panel 10 in accordance with an embodiment of the present disclosure. The bonding layer 200 enables the LED package PKC to be placed firmly to the display panel 10 and prevents the micro LEDs 210 from being detached.

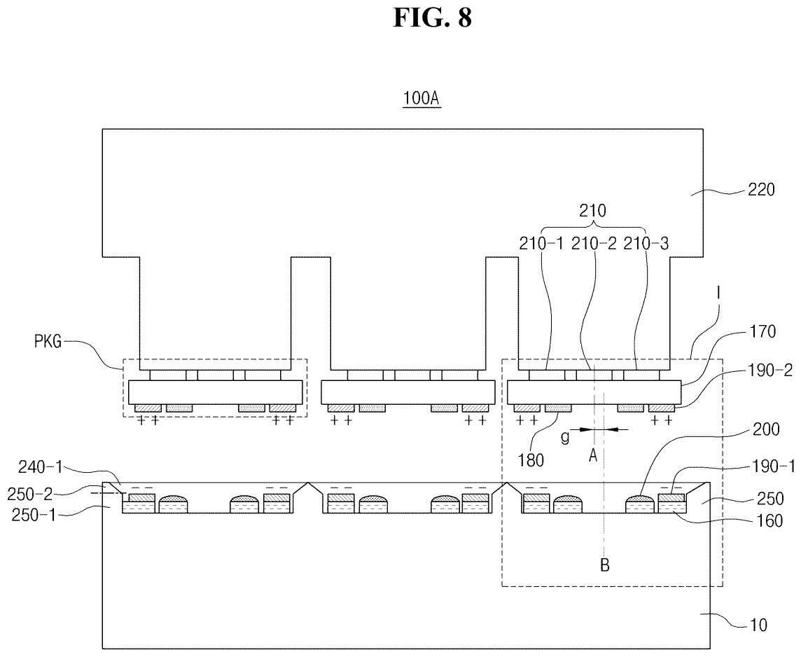

FIGS. 8 to 10 illustrate a schematic cross-sectional view of a display apparatus in accordance with another embodiment of the present disclosure. As illustrated in FIGS. 8 to 10, a display apparatus 100A further includes a protrusion 250 disposed on the display panel 10.

The protrusion 250 placed on the display panel 10 can be arranged to surround the LED package PKG and can act as a guide to arrange the LED package PKG at a set position on the display panel 10. In one embodiment, the protrusion 250 can comprise a first protrusion 250-1 protruded upwardly on the display panel 10 and a second protrusion 250-2 protruded on the first protrusion 250-1.

In one embodiment, a portion of the second protrusion 250-2 can be formed in a shape inclined at a certain angle from the first protrusion 250-1 so that light emitted from the LED package PKG can spread outwardly. In one embodiment, a plurality of protrusions 250 each of which surrounds each of the plural LED package PKG can be arranged on the display panel 10. In this case, the first protrusion 250-1 and/or the second protrusion 250-2 surrounding one LED package PKG, and the first protrusion 250-1 and/or the second protrusion 250-2 surrounding an adjacent LED package PKG may have shapes that are symmetrical to each other in left-right directions. In one embodiment, an upper surface of the support 170 can be placed at a substantially same position as an upper surface of the second protrusion 250-2.

If a central axis A of the LED package PKG transferred through the stamp 220 does not coincide with a central axis B of the display panel 10 and forma a certain gap g, an alignment error may occur due to the mismatch between the central axis A and the central axis B, so this problem can be corrected through the protrusion 250 guided to place the LED package PKG on the display panel 10.

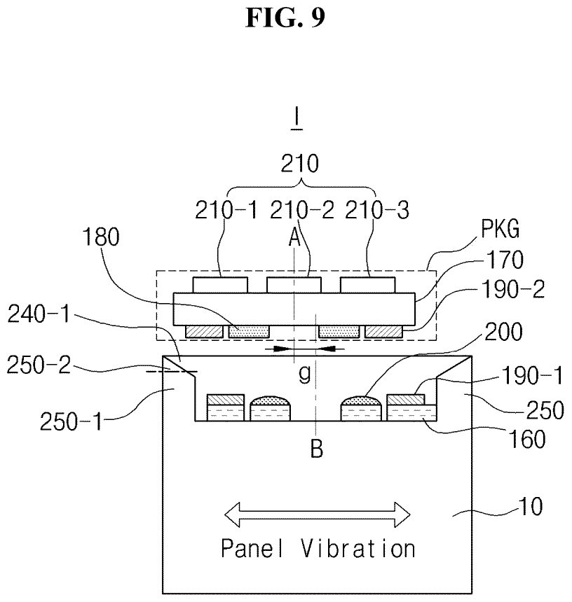

With referring to FIG. 9, a first fixing layer 240-1 can be disposed on the display panel 10. The first fixing layer 240-1 can be disposed to surround outsides of the adhesive layer 160, the first magnetic pad 190-1, the second magnetic pad 190-1, and the support 170. If necessary, the first fixing layer 250-1 can be disposed to surround outsides of the bonding layer 200 (FIG. 4) and the electrode 180.

For example, the first fixing layer 240-1 can comprise, but is not limited to, a fluid material with adhesive strength. The first fixing layer 240-1 can be cured by heat treatment after the LED package PKG is transferred to the display panel 10. The display panel 10 can be vibrated so that the LED package PKG can be placed correctly within the protrusion 250. As the display panel 10 vibrates, the LED package PKG can be guided at a set position. In this case, the support 170 of the LED package 170 collide with the protrusion 250 and the plural micro LEDs 210 can be transferred onto the display panel 10 without damage. The first fixing layer 240-1 can be cured during or after the LED package PKG is transferred onto the display panel 10.

A first arrangement can be made by magnetic force between the first magnetic pad 190-1 and the second magnetic pad 190-2, a second arranged can be made by vibrating the display panel 10, a third arrangement is made so that the LED package PKG does not deviate from the set position through the inclined surface of the second protrusion 250-2 of the protrusion 250, and a fourth arrangement can be made so that the LED package PKG can slide and settle on the display panel 10 due to the first fixing layer 240-1.

The above description is given for the various arrangement steps for the LED package PKG to improve accurate alignment and process yield when transferring extremely small micro LEDs 210, but is not limited to the order of the arrangements. Accordingly, it is possible to improve the transfer efficiency of the ultra-small micro LEDs 210 and minimize the area where misalignment occurs, and thereby proving a high quality display apparatus.

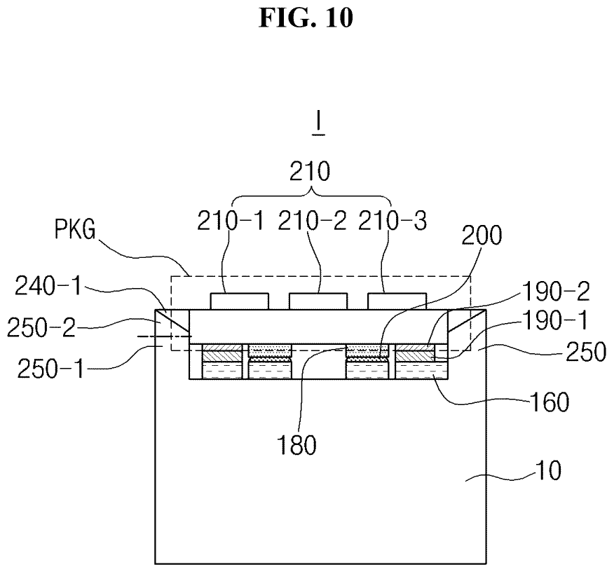

With referring to FIG. 10, an upper surface of the first fixing layer 240-1 can be designed and placed at a substantially same as an upper surface of the second protrusion 250-2 and/or the upper surface of the support 170. In this case, the first fixing layer 240-1 does not influence on the light emitted from the micro LEDs 210 so that the light efficiency of the LED package PKG can be maintained, the LED package can be fixed firmly to provide a much stable structure.

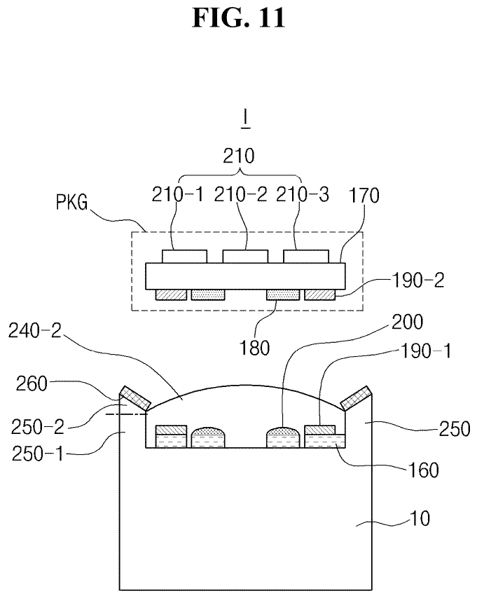

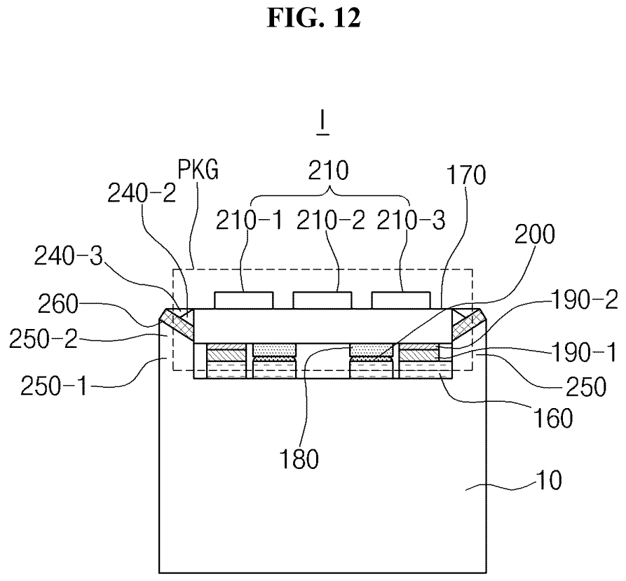

FIGS. 11 and 12 illustrate a display apparatus further including a nano coating layer 260 disposed on the protrusion 250. In one embodiment, the nano coating layer 260 can be placed on the inclined surface of the second protrusion 250-2. The nano coating layer 260 can comprise, but is not limited to, a superhydrophobic coating material. The superhydrophobic material is a material that makes water droplets hardly sticks to the surface and makes water roll off like beads. For example, the superhydrophobic coating material can comprise, but is not limited to, a fluorine-containing compound, for example, a fluorine-containing polymer (e.g. Teflon) and/or a fluorine-containing coating agents; a silicon-containing materials (e.g., siloxane, polydimethylsiloxane (PDMS)); a nanostructure-based material (e.g. silica nano particles, titanium dioxide (TiO₂) nano particles, etc.), Self-Assembled Monolayer (SAM), and the like. The waterproof properties of the nano coating layer 260 can prevent contamination that may be introduced from the outside.

In another embodiment, the display apparatus 100A can further comprise a second fixing layer 240-2 placed at least the support 170 on the display panel 10 in case the display apparatus 100A includes the nano coating layer 260.

A surface tension may occur in the second fixing layer 240-2 due to the nano coating layer 260, which is a superhydrophobic coating material, and thus, an agglomeration phenomenon may occur. The surface of the second fixing layer 240-2 where the agglomeration phenomenon occurred may have a round surface, unlike the first fixing layer 240-1 having a flat surface. When the display panel 10 is vibrated during LED package PKG transfer process, the second fixing layer 2402 with the rounded agglomerated surface can flow together with the nano coating layer 260. Due to the lubricating effect of the flowing second fixing layer 240-2 and the nano coating layer 260, it is possible to transfer the LED package PKG more smoothly and to align the LED package with precision.

In another embodiment, a third fixing layer 240-3 can be disposed on the second fixing layer 240-2 after the transfer of the LED package PKG on the display panel 10. In one embodiment, the third fixing layer 240-3 can be formed to the highest part of the protrusion 250 located on the display panel 10 and can play a role in making the surface of the protrusion 250 and/or the nano coating layer 260. The upper surface of the third fixing layer 240-3 can be arranged at a substantially same position of the upper surface of the support 170, thereby enabling the micro LEDs 210 to be transferred firmly without reducing luminous efficiency of the micro LEDs 210.

For example, each of the second fixing layer 240-2 and the third fixing layer 240-3 can comprise, but is not limited to, a fluid material with adhesive strength. The second fixing layer 240-2 and the third fixing layer 240-3 can be cured by heat treatment after the LED package PKG is transferred to the display panel 10.

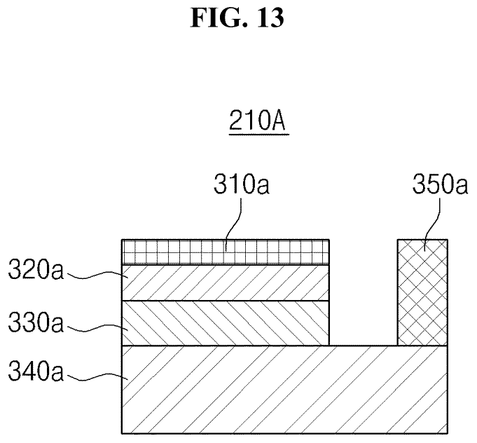

FIG. 13 illustrates a schematic cross-sectional view of a micro light-emitting diode in accordance with another embodiment of the present disclosure. The micro LED 210 can be a light-emitting diode with a lateral chip type.

As illustrated in FIG. 13, the micro LED 210A can comprise a p-type electrode 310a, a p-type semiconductor layer 320a on which the p-type electrode 310a is disposed, an active layer 330a disposed on the p-type semiconductor layer 320, an n-type semiconductor layer 340a disposed on the active layer 330a, and an n-type electrode 350 spaced apart from laterally form the p-type electrode 310 on the n-type semiconductor layer 340a. Both the p-type electrode 310a and the n-type electrode 350 can be electrically connected to the p-electrode and the n-electrode of the wiring board on the semiconductor light-emitting diode 210A unlike the flip chip type. However, the micro LEDs 210 is not limited to the structures of the lateral type chip 210A, and a light-emitting diode with the flip chip type can be applied as the micro LEDs 210.

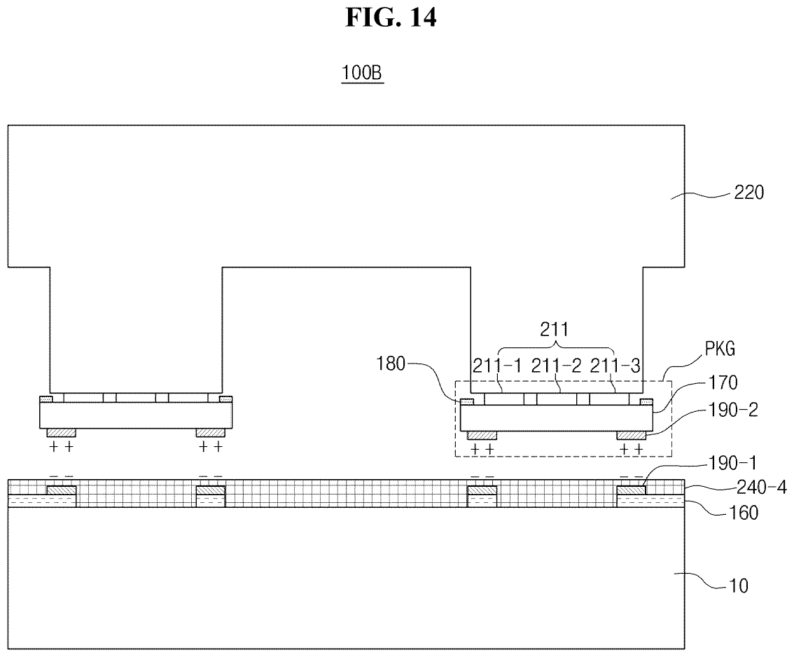

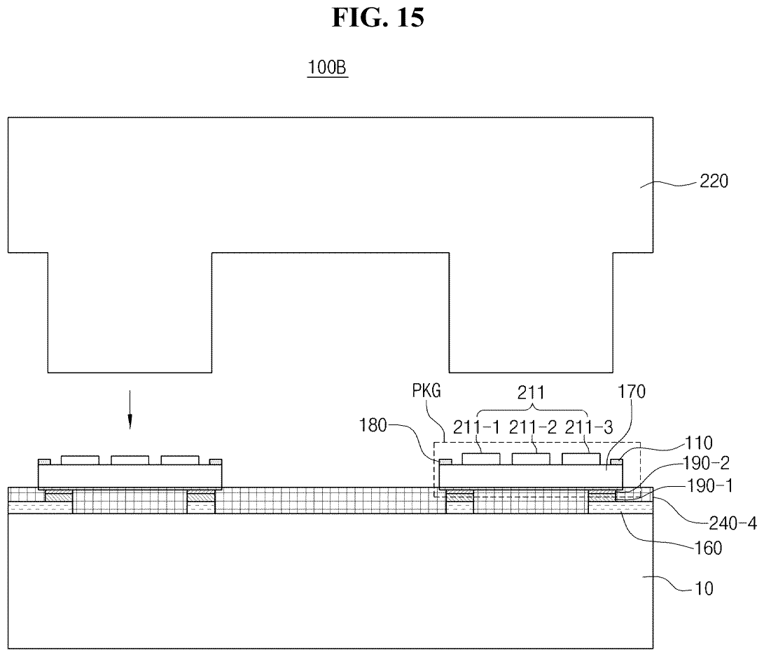

FIGS. 14 and 15 illustrate schematic cross-sectional views of a display apparatus in accordance with another embodiment of the present disclosure.

As illustrated in FIGS. 14 and 15, the electrode 180 in the LED package PKG is disposed on the support 170. In this case, the adhesive layers 160 and the first magnetic pad 190-1 can be arranged on the display panel 10, and the second magnetic pad 190-2 can be arranged under the support 170. The electrode 180 of the LED package PKG can be disposed on the support 170 with spaced apart from the plural micro LEDs 210.

In this case, the LED package PKG can be fixed onto the display panel 10 through a fourth fixing layer 240-4 instead of the bonding layer 200 (FIG. 4) for fixing the electrode 180. The fourth fixing layer 240-4 can be disposed on the entire display panel 10 with a certain height. In one embodiment, the height of the fourth fixing layer 240-4 can be equal to or less than the height of the support 170 of the transferred LED package PKG. For example, the third fourth layer 240-4 can comprise, but is not limited to, a fluid material with adhesive strength.

The fourth fixing layer 240-2 can be cured through heat treatment after the LED package PKG is aligned and transferred by the first magnetic pad 190-1 and the second magnetic pad 190-2. The LED package PKG can be stably attached to the display panel 10 even after transfer, and defects such as detachment can be prevented by the cured fourth fixing layer 240-4.

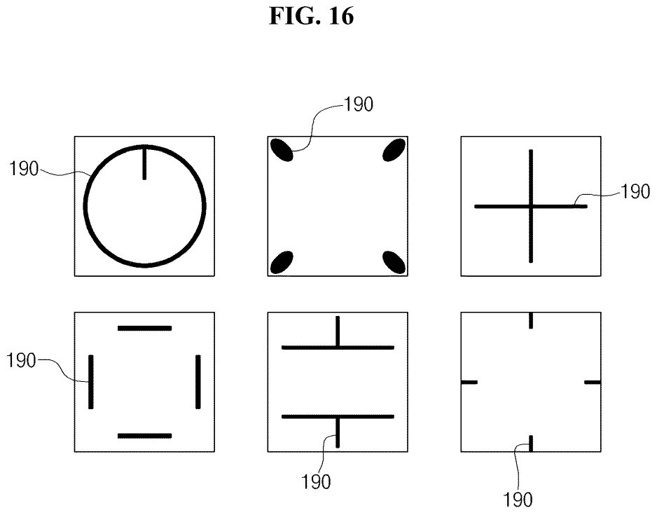

FIG. 16 illustrates various arrangements of a magnetic pad 190 in another embodiment of the present disclosure. As an example, the magnetic pad 190 including the first magnetic pad 190-1 and the second magnetic pad 190-2 can be disposed in multiples per the LED package PKG, and can have, but is not limited to, a linear shape or a curved shape.

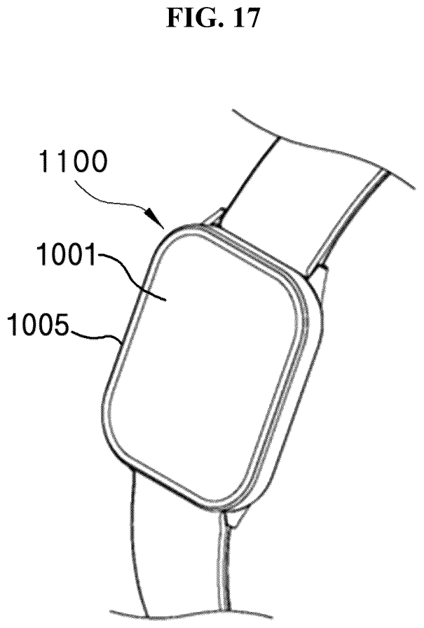

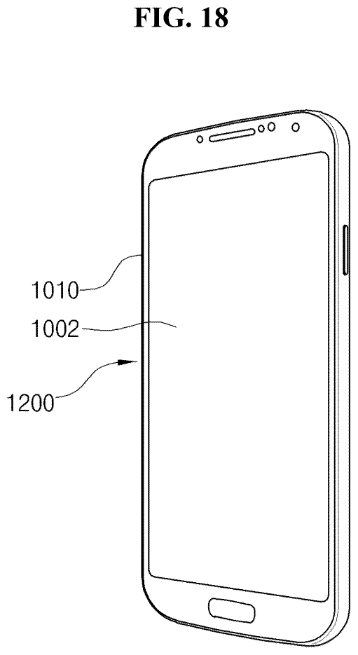

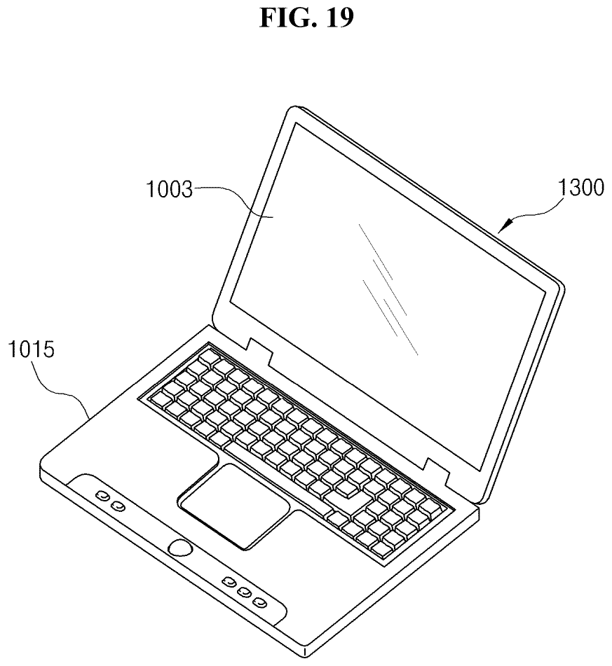

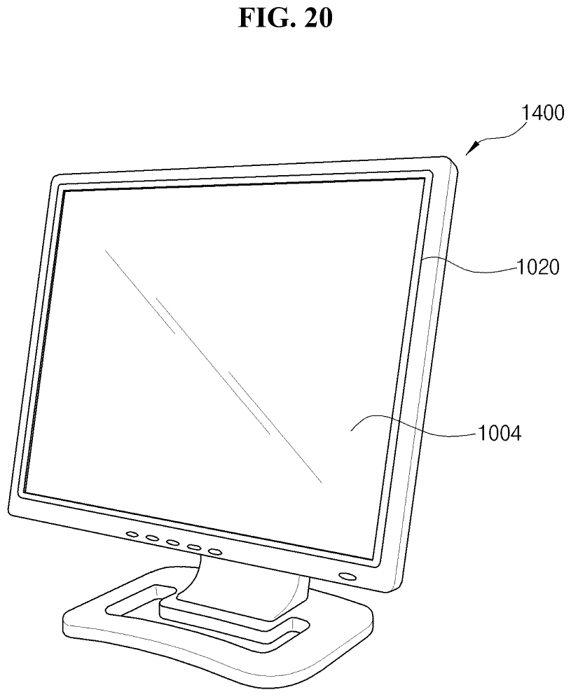

FIGS. 17 to 20 illustrate devices including the display apparatus in accordance with embodiments of the present disclosure.

With referring to FIGS. 17 to 20, the display apparatus 100, 100A or 100B (FIGS. 4, 7 and 14) in accordance with embodiments can be applied to various devices and/or electronic devices. For example, as illustrated in FIGS. 17 to 20, the electronic devices can comprise, but is not limited to, a wearable device 1100, a mobile device 1200, a notebook 1300 and a monitor or a television 1400.

In one embodiments, each of the wearable device 1100, the mobile device 1200, the notebook 1300 and the monitor or television 1400 can comprise a case portion 1005, 1010, 1015 or 1020, and the display panel 10 and/or the display apparatus 100, 100A or 100B as described with referring to FIGS. 1 to 16.

For example, the display apparatuses 1, 1A and/or 1B in embodiments of the present disclosure can be applied to a mobile device, a video phone, a smart watch, a watch phone, wearable devices, a foldable apparatus, a rollable apparatus, a bendable apparatus, a flexible apparatus, a curve apparatus, a sliding apparatus, a variable apparatus, an electronic notebook, an electronic book, a portable multimedia player (PMP), a personal digital assistant (PDA), an MP3 player, a mobile medical apparatus, a desktop PC, a laptop PC, a netbook computer, a workstation, a navigation apparatus, a display apparatus for a vehicle, a display apparatus for a theater, a television, a wallpaper apparatus, a signage apparatus, a game device, a notebook, a monitor, a camera, a camcorder, home appliances, and the like.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide examples of the technical features of the present disclosure for illustrative purposes. In other words, the disclosed embodiments are intended to illustrate the scope of the technical features of the present disclosure. Thus, the scope of the present disclosure is not limited to the embodiments shown, but is to be accorded the widest scope consistent with the claims. The scope of protection of the present disclosure should be construed based on the following claims, and all technical features within the scope of equivalents thereof should be construed as being included within the scope of the present disclosure.

What is claimed is:

1. A display apparatus, comprising:
a display panel;
a plurality of adhesive layers disposed on the display panel;
a first magnetic pad disposed on at least one of the plurality of adhesive layers; and
a light-emitting diode (LED) package disposed on the first magnetic pad.

2. The display apparatus of claim 1, wherein the LED package comprises:
a support;
a plurality of micro LEDs arranged on the support; and
a second magnetic pad positioned under the support.

3. The display apparatus of claim 2, wherein the LED package further comprises an electrode spaced apart from the second magnetic pad under the support.

4. The display apparatus of claim 3, wherein the display apparatus further comprises a plurality of bonding layers arranged on an adhesive layer on which the first magnetic pad is not arranged, and
wherein the adhesive layer is a layer among the plurality of adhesive layers.

5. The display apparatus of claim 4, wherein the electrode is disposed corresponding to each of the bonding layers.

6. The display apparatus of claim 3, wherein the first magnetic pad and the second magnetic pad have magnetic fields of different polarities.

7. The display apparatus of claim 3, wherein the second magnetic pad is positioned correspondingly on the first magnetic pad.

8. The display apparatus of claim 3, wherein the second magnetic pad is arranged in multiples per the LED package.

9. The display apparatus of claim 3, wherein the display panel further comprises a protrusion disposed to surround the LED package.

10. The display apparatus of claim 9, wherein the protrusion comprises:
a first protrusion protruding upwardly from an upper surface of the display panel; and
a second protrusion having a shape inclined from an upper surface of the first protrusion.

11. The display apparatus of claim 10, wherein an upper surface of the support is placed at a substantially same position as an upper surface of the second protrusion.

12. The display apparatus of claim 10, wherein the display apparatus further comprises a first fixing layer disposed on the display panel and disposed to surround outer sides of an adhesive layer, the first magnetic pad, the second magnetic pad and the support, and
wherein the adhesive layer is a layer among the plurality of adhesive layers.

13. The display apparatus of claim 12, wherein an upper surface of the first fixing layer is placed at a substantially same as an upper surface of the second protrusion.

14. The display apparatus of claim 10, wherein the display panel further comprises a nano coating layer disposed on the second protrusion.

15. The display apparatus of claim 14, wherein the display apparatus further comprises:
a second fixing layer placed on the display panel and arranged to surround a portion of an outside of the support; and
a third fixing layer disposed on the second fixing layer.

16. The display apparatus of claim 2, wherein the display apparatus further comprises a fourth fixing layer disposed on the display panel and arranged to surround the plurality of adhesive layers, the first magnetic pad and the second magnetic pad.

17. The display apparatus of claim 2, wherein the first magnetic pad and the second magnetic pad have magnetic fields of different polarities, and the second magnetic pad is positioned correspondingly on the first magnetic pad.

18. The display apparatus of claim 1, wherein the first magnetic pad is arranged in multiples per the LED package.

19. A process of fabricating a display apparatus, the process comprising:
arranging a plurality of adhesive layers on a display panel;
arranging a first magnetic pad on the plurality of the adhesive layers; and
arranging a light-emitting diode (LED) package on the first magnetic pad,
wherein the LED package comprises a second magnetic pad having a magnetic field, wherein a polarity of the magnetic field of the second magnetic pad is opposite to a polarity of a magnetic field of the first magnetic pad, and
wherein the second magnetic pad is placed on the first magnetic pad by magnetism.

20. The process of claim 19, wherein the display panel further comprises a protrusion disposed to surround the LED package.

21. The process of claim 19, wherein the display panel is vibrated to align a central axis of the LED package with a central axis of the display panel when the second magnetic pad is placed on the first magnetic pad by magnetism.
